(19) United States
(12) Patent Application Publication
(10) Pub. No.: US 2025/0151468 A1
(43) Pub. Date: May 8, 2025

(54) DISPLAY PANEL

(71) Applicants: TCL CHINA STAR OPTOELECTRONICS TECHNOLOGY CO., LTD., Shenzhen (CN); South China University of Technology, Guangzhou (CN)

(72) Inventors: Jiangbo YAO, Shenzhen (CN); Junbiao PENG, Shenzhen (CN); Changming XIANG, Shenzhen (CN); Rui ZHAO, Shenzhen (CN); Weiji ZHANG, Shenzhen (CN)

(73) Assignees: TCL CHINA STAR OPTOELECTRONICS TECHNOLOGY CO., LTD., Shenzhen (CN); South China University of Technology, Guangzhou (CN)

(21) Appl. No.: 18/513,698

(22) Filed: Nov. 20, 2023

(30) Foreign Application Priority Data
Nov. 6, 2023 (CN) 202311464163.0

(51) Int. Cl. H01L 33/20; H01L 25/075; H01L 25/16; H01L 27/12; H01L 27/15; H01L 33/62

(52) U.S. Cl. CPC H10H 20/819; H01L 25/0753; H01L 25/167; H10D 86/441; H10D 86/60; H10H 20/857; H10H 29/142

(57) ABSTRACT

Disclosed is a display panel. The display panel includes a substrate, first interlayer disposed on the substrate, and a light-emitting element layer disposed on one side of the first interlayer away from the substrate. A plurality of first convex portions are disposed on one side of the first interlayer away from the substrate. The light-emitting element layer includes a plurality of light-emitting elements disposed on the plurality of first convex portions. At least some of the plurality of light-emitting elements are disposed on side walls of the plurality of first convex portions. A light-emitting surface of each of the plurality of light-emitting elements extends in a first direction, an included angle formed between the first direction and a second direction is an acute angle, and the second direction is a direction in which the substrate points towards the first interlayer.

### CROSS-REFERENCE TO RELATED APPLICATION

The present disclosure claims priority to and the benefit of Chinese Patent Application No. 202311464163.0, filed on August Nov. 6, 2023, the disclosure of which is incorporated herein by reference in its entirety.

### TECHNICAL FIELD

The present disclosure relates to the field of display technology, and in particular, to a display panel.

### BACKGROUND OF INVENTION

3D display, as a new display technology, has great development prospects in the future, such as in-vehicle display, indoor cinemas, outdoor advertising, High-end establishment display (yachts, aircraft, etc.). It has a wide range of applications, and it can provide customers with more stereoscopic and vivid display information.

Currently, display panels for realizing 3D display mainly include raster display panels and column lenticular display panels. However, due to the structural limitations, the above two display panels for 3D display have relatively small viewing angles, making it difficult to realize large viewing angle display.

### SUMMARY OF INVENTION

Some embodiments of the present disclosure provide a display panel capable of increasing the light-emitting angle of the display panel and increasing the viewing angle range of the display panel.

Some embodiments of the present disclosure provide a display panel, which includes:
a substrate;
a first interlayer disposed on the substrate, wherein a plurality of first convex portions are disposed on one side of the first interlayer away from the substrate; and
a light-emitting element layer disposed on one side of the first interlayer away from the substrate, wherein the light-emitting element layer includes a plurality of light-emitting elements disposed on the plurality of first convex portions;
wherein at least some of the plurality of light-emitting elements are disposed on side walls of the plurality of first convex portions, a light-emitting surface of each of the plurality of light-emitting elements extends in a first direction, an included angle formed between the first direction and a second direction is an acute angle, and the second direction is a direction in which the substrate points towards the first interlayer.

In some embodiments of the present disclosure, the display panel further includes a second interlayer disposed on one side of the light-emitting element layer away from the first interlayer and covering the plurality of light-emitting elements, wherein a plurality of second convex portions are disposed on one side of the second interlayer away from the light-emitting element layer, and each of the plurality of first convex portions is disposed correspondingly with each of the plurality of second convex portions in the second direction N.

In some embodiments of the present disclosure, the display panel further includes a light-shielding grating layer disposed on one side of the second interlayer away from the light-emitting element layer, and the light-shielding grating layer comprising a plurality of first light-shielding portions and a plurality of second light-shielding portions that are alternately disposed at intervals;
wherein the plurality of first light-shielding portions are disposed on top surfaces of the plurality of second convex portions, and the plurality of second light-shielding portions are disposed between two adjacent ones of the plurality of second convex portions.

In some embodiments of the disclosure, an orthographic projection of each of the plurality of light-emitting elements on the substrate is disposed between orthographic projections of one of the plurality of first light-shielding portions and one of the plurality of second light-shielding portions adjacent to one of the plurality of first light-shielding portions on the substrate.

In some embodiments of the present disclosure, each of the plurality of first convex portions comprises two first side walls, and each of the plurality of first convex portions comprises two second side walls disposed opposite to the two first side walls in the second direction;
wherein at least one of the plurality of light-emitting elements is disposed on one of the first side walls, a first light-shielding portion and a second light-shielding portion are disposed at two opposite ends of each of the second side walls, respectively, each of the first side walls is planar or curved, and each of the second side walls is planar or curved.

In some embodiments of the present disclosure, a first connection line between one of the plurality of first light-shielding portions and one of the plurality of second light-shielding portions disposed at the two opposite ends of each of the second side walls is parallel to the light-emitting surface of each of the plurality of light-emitting elements disposed on one of the first side walls.

In some embodiments of the disclosure, each of the plurality of light-emitting elements is disposed on a perpendicular bisector of the first connection line.

In some embodiments of the present disclosure, the display panel further includes a third interlayer disposed on one side of the light-shielding grating layer away from the second interlayer, a cover plate disposed on one side of the third interlayer away from the light-shielding grating layer, wherein the third interlayer is filled at least between adjacent ones of the plurality of second convex portions.

In some embodiments of the present disclosure, a cross-sectional shape of each of the plurality of first convex portions is one of a trapezoidal shape, a triangular shape, a circular arc shape, or an elliptical arc shape, and each of the plurality of second convex portions is one of a trapezoidal shape, a triangular shape, a circular arc shape, or an elliptical arc shape.

In some embodiments of the present disclosure, the display panel further includes a driving circuit layer disposed between the substrate and the first interlayer, and a signal wiring disposed between the first interlayer and the light-emitting element layer, wherein the plurality of light-emitting elements are connected to the signal wiring, and the signal wiring penetrates through the first interlayer and is connected to the driving circuit layer.

According to the present disclosure, a first interlayer is disposed between a light-emitting element layer and a substrate, and a plurality of first convex portions are disposed on one side of the first interlayer away from the substrate, and a plurality of light-emitting elements in the light-emitting element layer are disposed on side walls of the first convex portions, so that light-emitting surface of each of the plurality of light-emitting elements extends in a first direction. Further, an included angle formed between the first direction and a second direction is an acute angle, and the second direction is a direction in which the substrate points towards the first interlayer, so that light emitted by the light-emitting elements can be obliquely in the positive direction, thus increasing the light-emitting angles of the light-emitting element layer, thereby increasing the viewing angle range of the display panel.

### BRIEF DESCRIPTION OF THE DRAWINGS

The technical solutions and other beneficial effects of the present disclosure will be apparent from the detailed description of specific embodiments of the present disclosure with reference to the accompanying drawings.

FIG. 1 is a schematic structural diagram of a display panel according to some embodiments of the present disclosure.

FIG. 2 is a schematic diagram of a planar distribution of a light blocking grating layer and a light emitting device layer according to some embodiments of the present disclosure.

FIG. 3 is a schematic diagram of a display panel in another configuration according to some embodiments of the present disclosure.

FIG. 4 is a schematic diagram of a display panel in still another configuration according to some embodiments of the present disclosure.

FIG. 5 is a schematic diagram of a display panel in further another configuration according to some embodiments of the present disclosure.

### EMBODIMENTS OF INVENTION

Hereinafter, technical solutions in embodiments of the present disclosure will be clearly and completely described with reference to the accompanying drawings in embodiments of the present disclosure. Apparently, the described embodiments comprise but are not limited to the embodiments of the present disclosure. Other embodiments that can be obtained by a person with ordinary skill in the art on the basis of the embodiments in the present disclosure without creative labor belong to the protection scope of the present disclosure.

The following description provides different embodiments or examples for implementing different structures of the present disclosure. In order to simplify the present disclosure, components and arrangements of specific examples are described below. It is clear that they are merely examples and are not intended to limit the present disclosure. In addition, reference numerals and/or reference letters are repeated in different examples. Such repetition is for the purpose of simplification and clarity, and it does not indicate the relationship between the various embodiments and/or settings discussed. Furthermore, the present disclosure provides examples of various specific processes and materials, but people of ordinary skill in the art may be aware of the application of other processes and/or the use of other materials.

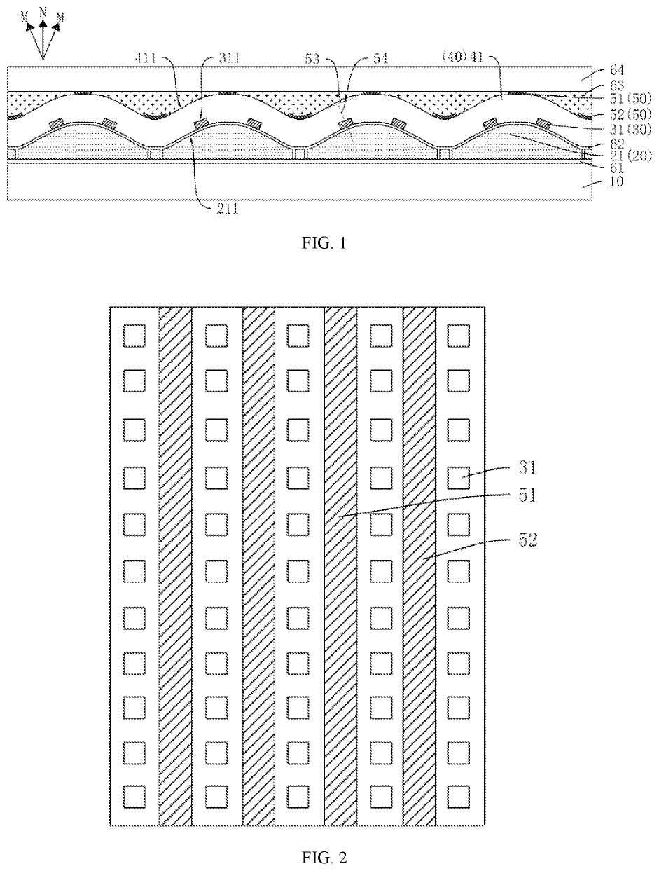

Some embodiment of the present disclosure provide a display panel. Referring to FIG. 1, the display panel includes a substrate 10, a first interlayer 20, and a light-emitting element layer 30.

The first interlayer 20 is disposed on the substrate 10, and a plurality of first convex portions 21 are disposed on one side of the first interlayer 20 away from the substrate 10. The light-emitting element layer 30 is disposed on one side of the first interlayer 20 away from the substrate 10, and the light-emitting element layer 20 includes a plurality of light-emitting elements 31 disposed on the plurality of first convex portions 21.

Further, at least some of the plurality of light-emitting elements 31 are disposed on side walls of the plurality of first convex portions 21. A light-emitting surface 311 of each of the plurality of light-emitting elements 31 extends in a first direction M, an included angle formed between the first direction M and a second direction Nis an acute angle, and the second direction N is a direction in which the substrate 10 towards the first interlayer 20.

According to some embodiments of the present disclosure, a first interlayer 20 is disposed between a light-emitting element layer 30 and a substrate 10, and a plurality of first convex portions 21 are disposed on one side of the first interlayer 20 away from the substrate 10, and a plurality of light-emitting elements 31 in the light-emitting element layer 30 are disposed on side walls of the first convex portions 21, so that light-emitting surface 311 of each of the plurality of light-emitting elements 31 extends in a first direction M. Further, an included angle formed between the first direction M and a second direction Nis an acute angle, and the second direction N is a direction in which the substrate 10 points towards the first interlayer 20, so that light emitted by the light-emitting elements 31 can be obliquely in the positive direction, thus increasing the light-emitting angles of the light-emitting element layer 30, thereby increasing the viewing angle range of the display panel.

Exemplarily, please continue to refer to FIG. 1, the display panel further includes a driving circuit layer 61 disposed between the substrate 10 and the first interlayer 20, a signal wiring 62 disposed between the light-emitting element layer 30 and the first interlayer 20, a second interlayer 40 disposed one side of the light-emitting element layer 30 away from the first interlayer 20, a light-shielding grating layer 50 disposed on one side of the second interlayer 40 away from the light-emitting element layer 30, a third interlayer 63 disposed on one side of the light-shielding grating layer 50 away from the second interlayer 40, and a cover plate 64 disposed on one side of the third interlayer 63 away from the light-shielding grating layer 50.

The substrate 10 may be a glass substrate or a resin substrate. The light-emitting element 31 may be an LED lamp, for example, may be an LED lamp bead or an LED chip. The material of both the first interlayer 20 and the third interlayer 63 may include an epoxy resin, a polymethyl methacrylate, or a polycarbonate. The material of the second interlayer 40 may be a transparent encapsulating adhesive. The material of the light-shielding grating layer 50 may include an epoxy resin material doped with black graphene, a polymethyl methacrylate material doped with black graphene, or a polycarbonate material doped with black graphene. The light-shielding grating layer 50 may also use a black matrix (BM) material.

The driving circuit layer 61 is disposed on the substrate 10, and the driving circuit layer 61 may include circuit units. The first interlayer 20 is disposed on the substrate 10 and may cover the driving circuit layer 61. The signal wiring 62 may penetrate through the first interlayer 20 and be connected to circuit units in the driving circuit layer 61, and the light-emitting elements 31 in the light-emitting element layer 30 are connected to the signal wiring 62, so that signal in the circuit units can be transmitted to the light-emitting elements 31 to make the light-emitting element 31 emit light.

In some embodiments of the present disclosure, a plurality of first convex portions 21 are disposed on one side of the first interlayer 20 away from the substrate 10, and a plurality of light-emitting elements 31 are disposed on the plurality of first convex portions 21. Exemplarily, at least some of the plurality of light-emitting elements 31 are disposed on side walls of the plurality of first convex portions 21, so that the light-emitting surface 311 of each of the plurality of light-emitting elements 31 extends in a first direction M. An included angle formed between the first direction M and a second direction Nis an acute angle, and the second direction N is a direction in which the substrate 10 points towards the first interlayer 20, so that the facing direction of the light-emitting surface 311 of the light-emitting elements 31 is deviated from the positive direction of the display panel, that is, is deviated from the second direction N, which increases the oblique light emitted by the display panel, thereby increasing the light-emitting angles and viewing angle range of the display panel.

In some embodiments, all of the light-emitting elements 31 in the light-emitting element layer 30 are disposed on the side walls of the first convex portions 21. Each of the first convex portions 21 includes two opposite side walls, and at least one light-emitting element 31 is disposed on one of the opposite two side walls of the first convex portion 21, so that the first directions M in which each light-emitting surface 311 of the light-emitting elements 31 extends can be respectively located on both sides of the second direction N, so as to further increase the light-emitting angles and the viewing angle range of the display panel.

The second interlayer 40 covers the plurality of light-emitting elements 31, and a plurality of second convex portions 41 are disposed on one side of the second interlayer 40 away from the light-emitting element layer 30. Each of the plurality of first convex portions 41 is disposed correspondingly with each of the plurality of second convex portions 21 in the second direction N.

The light-shielding grating layer 50 includes a plurality of first light-shielding portions 51 and a plurality of second light-shielding portions 52 disposed on the plurality of second convex portions 41, wherein the plurality of first light-shielding portions 51 and the plurality of second light-shielding portions 52 are alternately disposed at intervals. Exemplarily, one second light-shielding portion 52 is disposed between two adjacent first light-shielding portions 51, and one first light-shielding portion 51 is disposed between two adjacent second light-shielding portions 52.

Referring to FIGS. 1 and 2, in some embodiments of the present disclosure, an orthographic projection of each of the plurality of light-emitting elements 31 on the substrate 10 is disposed between orthographic projections of one of the plurality of first light-shielding portions 51 and one of the plurality of second light-shielding portions 52 adjacent to one of the plurality of first light-shielding portions 51 on the substrate 10. On the one hand, the light-shielding grating layer 50 can prevent light crosstalk between adjacent light-emitting elements 31. On the other hand, the plurality of first light-shielding portions 51 and the plurality of second light-shielding portions 52 are sequentially disposed to form a grating structure, so that 3D display function of the display panel can be realized through the slits of the grating structure when the plurality of light-emitting elements 31 emit light towards the light-shielding grating layer 50. Furthermore, in the embodiments of the present disclosure, the light-emitting elements 31 are disposed on the side walls of the first convex portions 21, so that the viewing angle range of the 3D display panel can be increased while realizing 3D display.

Continuing to refer to FIG. 1, the plurality of first light-shielding portions 51 are disposed on top surfaces of the plurality of second convex portions 41, and the plurality of second light-shielding portions 52 are disposed between two adjacent ones of the plurality of second convex portions 41 to expose the side walls of the second convex portions 41. Since the first convex portions 21 and the second convex portions 41 are disposed in alignment along the second direction N, the side walls of the first convex portions 21 can be exposed, so that the light-emitting elements 31 located on the side walls of the first convex portions 21 can be exposed to emit light.

In some embodiments, each first convex portion 21 includes two first side walls 211, and the each second convex portion 41 includes two second side wall 411 disposed opposite to the first side walls 211 in the second direction N. A light-emitting element 31 is disposed on each first side wall 211. Each second side wall 411 has two opposite ends, and a first light-shielding portion 51 and a second light-shielding portion 52 are disposed at the two opposite ends, respectively. A connection line between the first light shielding portion 51 and the second light shielding portion 52 at the opposite ends of one second side wall 411 is set as the first connection line 53, and the first connection line 53 is parallel to the light-emitting surface 311 of the light emitting element 31 on one first side wall 211 corresponding to second side wall 411. Further, one light-emitting element 31 located on the first side wall 211 may be located on a perpendicular bisector 54 of one first connection line 53, so that the light-shielding effect of the first light-shielding portion 51 and the second light-shielding portion 52 at the opposite ends of the second side wall 411 on the light-emitting element 31 located on the first side wall 211 is uniform and symmetrical, thereby improving light uniformity and symmetry of the light-emitting element 31 and improving the display effect of the display panel. It can be understood that the positions of the other light-emitting elements 31 in the light-emitting element layer 30 and the other first light-shielding portions and second light-shielding portions in the light-shielding grating layer 50 can be disposed with reference to the above-described embodiments, so as to improve the display effect of the display panel.

In some embodiments, each of the first side walls 211 and each of the second side walls 411 can be independently selected from a plane or an arc surface, and the cross-sectional shapes of each of the first convex portion 21 and each of the second convex portion 41 may each be independently selected from one of a trapezoidal shape, a triangular shape, a circular arc shape, and an elliptical arc shape.

In some embodiments, the first side walls 211 and the second side walls 411 are disposed in parallel.

In some embodiments of the present disclosure, as shown in FIG. 1, both the cross-sectional shapes of the first convex portions 21 and the second convex portions 41 can be circular arc shapes, and both the first side walls 211 and the second side walls 411 are curved.

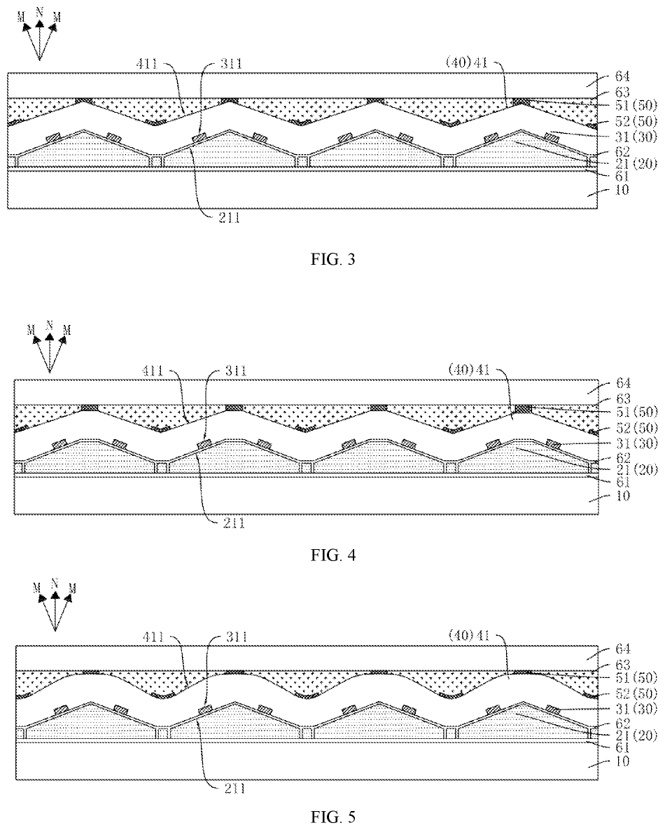

In some embodiments of the present disclosure, as shown in FIG. 3, both the cross-sectional shapes of the first convex portions 21 and the second convex portions 41 can be triangular shapes, and both the first side walls 211 and the second side walls 411 are planar.

In some embodiments of the present disclosure, as shown in FIG. 4, both the cross-sectional shapes of the first convex portions 21 and the second convex portions 41 can be trapezoidal shapes, and both the first side walls 211 and the second side walls 411 are planar.

In some embodiments of the present disclosure, as shown in FIG. 5, the cross-sectional shapes of the first convex portions 21 may be circular arc shapes, while the cross-sectional shapes of the second convex portions 41 may be circular arc shapes, and the first side walls 211 are planar, and the second side walls 411 are curved.

It should be noted that the first convex portions 21 and the second convex portions 41 may be other polygons, or the like, and the shapes of the plurality of first convex portions 21 may be the same or different, and the shapes of the plurality of second convex portions 41 may be the same or different, but it is necessary to form an acute angle between the first direction M in which the light-emitting surface 311 of the light-emitting element 31 extends and the second direction N, so as to increase the light-emitting angles of the display panel while realizing normal light emission.

In addition, the first interlayer 20 includes a plurality of first convex portions 21, and the included angle between each of the side walls of the plurality of first convex portions 21 and the substrate 10 may be the same or different, so that the orientation of the first direction M may be controlled by controlling the included angles between the side walls of the first convex portions 21 and the substrate 10. Alternatively, the first directions M of the light-emitting elements 31 in different areas may be set to be different according to display requirements of different areas of the display panel, for example, in an area where the brightness of the display panel is dark, the included angles between the first directions M and the second directions N may be reduced to improve the brightness of the display panel, thereby satisfying more display requirements of the display panel.

Furthermore, the third interlayer 63 covers the light-shielding grating layer 50 and fills between adjacent second projections 41, and the cover plate 64 is disposed on the side of the third interlayer 63 away from the light-shielding grating layer 50.

It should be noted that, in the embodiments of the present disclosure, the first interlayer 20, the second interlayer 40, and the third interlayer 63 can all be molded at one time by film pressing, and a plurality of openings can be formed in the first interlayer 20 by laser drilling, so that the signal wirings 62 can penetrate through the openings and be connected to the driving circuit layer 61.

In view of above, in the embodiments of the present disclosure, a first interlayer 20 is disposed between a light-emitting element layer 30 and a substrate 10, and a plurality of first convex portions 21 are disposed on one side of the first interlayer 20 away from the substrate 10, and a plurality of light-emitting elements 31 in the light-emitting element layer 30 are disposed on side walls of the first convex portions 21, so that light-emitting surface 311 of each of the plurality of light-emitting elements 31 extends in a first direction M. Further, an included angle formed between the first direction M and a second direction Nis an acute angle, and the second direction N is a direction in which the substrate 10 points towards the first interlayer 20, so that light emitted by the light-emitting elements 31 can be obliquely in the positive direction, thus increasing the light-emitting angles of the light-emitting element layer 30, thereby increasing the viewing angle range of the display panel

In addition, some embodiments of the present disclosure further provide a display device including the display panel described in the above embodiments. The display device can be used for 3D display, since the light emitting elements 31 are disposed on the side walls of the first convex portions 21, the light-emitting angles can be increased, so that the viewing angle range of the display device can be increased.

Since the display device provided in the embodiments of the present disclosure has the same display panel as that in the above-described embodiments, the display device provided in the embodiments of the present disclosure also has the same beneficial effect as the display panel in the above-described embodiments, and details are not described herein.

In the above-mentioned examples, the description of each example has its own focus. For parts that are not described in detail in an example, please refer to related descriptions of other examples.

In view of the foregoing, the display panel provided in the embodiments of the present disclosure have been described in detail above, and the principles and embodiments of the present disclosure are described by using specific examples herein. Descriptions of the above examples are merely intended to help understand the technical solutions and core ideas of the present disclosure. A person with ordinary skill in the art should understand that various modifications may still be made to the technical solutions described in the foregoing embodiments, or equivalents may be made to some of the technical features therein. These modifications or substitutions do not depart the essence of the corresponding technical solutions from the scope of the technical solutions of the examples of the present disclosure.

What is claimed is:

1. A display panel, comprising:
a substrate;
a first interlayer disposed on the substrate, a plurality of first convex portions being disposed on one side of the first interlayer away from the substrate; and
a light-emitting element layer disposed on one side of the first interlayer away from the substrate, the light-emitting element layer comprising a plurality of light-emitting elements disposed on the plurality of first convex portions;
wherein at least some of the plurality of light-emitting elements are disposed on side walls of the plurality of first convex portions, a light-emitting surface of each of the plurality of light-emitting elements extends in a first direction, an included angle formed between the first direction and a second direction is an acute angle, and the second direction is a direction in which the substrate points towards the first interlayer.

2. The display panel according to claim 1, further comprising a second interlayer disposed on one side of the light-emitting element layer away from the first interlayer and covering the plurality of light-emitting elements, wherein a plurality of second convex portions are disposed on one side of the second interlayer away from the light-emitting element layer, and each of the plurality of first convex portions is disposed correspondingly with each of the plurality of second convex portions in the second direction.

3. The display panel according to claim 2, further comprising a light-shielding grating layer disposed on one side of the second interlayer away from the light-emitting element layer, and the light-shielding grating layer comprising a plurality of first light-shielding portions and a plurality of second light-shielding portions that are alternately disposed at intervals;
wherein the plurality of first light-shielding portions are disposed on top surfaces of the plurality of second convex portions, and the plurality of second light-shielding portions are disposed between two adjacent ones of the plurality of second convex portions.

4. The display panel according to claim 3, wherein an orthographic projection of each of the plurality of light-emitting elements on the substrate is disposed between orthographic projections of one of the plurality of first light-shielding portions and one of the plurality of second light-shielding portions adjacent to one of the plurality of first light-shielding portions on the substrate.

5. The display panel according to claim 3, wherein each of the plurality of first convex portions comprises two first side walls, and each of the plurality of first convex portions comprises two second side walls disposed opposite to the two first side walls in the second direction;
wherein at least one of the plurality of light-emitting elements is disposed on one of the first side walls, a first light-shielding portion and a second light-shielding portion are disposed at two opposite ends of each of the second side walls, respectively, each of the first side walls is planar or curved, and each of the second side walls is planar or curved.

6. The display panel according to claim 5, wherein a first connection line between one of the plurality of first light-shielding portions and one of the plurality of second light-shielding portions disposed at the two opposite ends of each of the second side walls is parallel to the light-emitting surface of each of the plurality of light-emitting elements disposed on one of the first side walls.

7. The display panel according to claim 6, wherein each of the plurality of light-emitting elements is disposed on a perpendicular bisector of the first connection line.

8. The display panel according to claim 3, further comprising a third interlayer disposed on one side of the light-shielding grating layer away from the second interlayer, and a cover plate disposed on one side of the third interlayer away from the light-shielding grating layer, wherein the third interlayer is filled at least between adjacent ones of the plurality of second convex portions.

9. The display panel according to claim 2, wherein a cross-sectional shape of each of the plurality of first convex portions is one of a trapezoidal shape, a triangular shape, a circular arc shape, or an elliptical arc shape, and each of the plurality of second convex portions is one of a trapezoidal shape, a triangular shape, a circular arc shape, or an elliptical arc shape.

10. The display panel according to claim 1, further comprising a driving circuit layer disposed between the substrate and the first interlayer, and a signal wiring disposed between the first interlayer and the light-emitting element layer, wherein the plurality of light-emitting elements are connected to the signal wiring, and the signal wiring penetrates through the first interlayer and is connected to the driving circuit layer.

11. The display panel according to claim 1, wherein the substrate may be a glass substrate or a resin substrate.

12. The display panel according to claim 1, wherein each of the plurality of light-emitting elements is an LED lamp bead or an LED chip.

13. The display panel according to claim 1, wherein a material of the first interlayer comprises an epoxy resin, a polymethyl methacrylate, or a polycarbonate.

14. The display panel according to claim 2, wherein a material of the second interlayer is a transparent encapsulating adhesive.

15. The display panel according to claim 8, wherein a material of the third interlayer comprises an epoxy resin, a polymethyl methacrylate, or a polycarbonate.

16. The display panel according to claim 3, wherein a material of the light-shielding grating layer comprises an epoxy resin material doped with black graphene, a polymethyl methacrylate material doped with black graphene, or a polycarbonate material doped with black graphene.

17. The display panel according to claim 3, wherein a material of the light-shielding grating layer is a black matrix material.

18. The display panel according to claim 5, wherein each of the first side walls is disposed in parallel with each of the second side walls.

19. The display panel according to claim 8, wherein the first interlayer, the second interlayer, and the third interlayer are molded at one time by film pressing.

20. A display device comprising a display panel, wherein the display panel comprises:
a substrate;
a first interlayer disposed on the substrate, a plurality of first convex portions being disposed on one side of the first interlayer away from the substrate; and
a light-emitting element layer disposed on one side of the first interlayer away from the substrate, and the light-emitting element layer comprises a plurality of light-emitting elements disposed on the plurality of first convex portions;
wherein at least some of the plurality of light-emitting elements are disposed on side walls of the plurality of first convex portions, a light-emitting surface of each of the plurality of light-emitting elements extends in a first direction, an included angle formed between the first direction and a second direction is an acute angle, and the second direction is a direction in which the substrate points towards the first interlayer.
